(19) United States
(12) Patent Application Publication
(10) Pub. No.: US 2024/0306469 A1
(43) Pub. Date: Sep. 12, 2024

(54) DISPLAY MODULE AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Chao ZHOU, Beijing (CN); Liqiang CHEN, Beijing (CN); Jiafan SHI, Beijing (CN); Zuojia WANG, Beijing (CN); Chuandong LIAO, Beijing (CN); Feitong PENG, Beijing (CN)

(21) Appl. No.: 18/245,093

(22) PCT Filed: Apr. 28, 2022
(86) PCT No.: PCT/CN2022/089967

§ 371 Date: Mar. 13, 2023

(51) Int. Cl. H10K 59/80; G06V 40/13; H10K 59/35; H10K 102/00

(52) U.S. Cl. CPC H10K 59/80; H10K 59/8792; G06V 40/1318; H10K 59/353; H10K 2102/311

(57) ABSTRACT

A display module and a display apparatus are provided. The display module includes a display panel and a support layer. The support layer is disposed on a non-display side of the display panel; the support layer includes a support plate and a first support part connected with the support plate. The support plate is provided with a first hole, and the first support part is disposed in the first hole; at least a portion of the first support part is light permeable. A side surface of the support plate proximate to the display panel is substantially flush with a side surface of the first support part proximate to the display panel. A thickness of the support layer is in a range of approximately 10 μm to approximately 200 μm, inclusive.

### CROSS-REFERENCE TO RELATED APPLICATION

This application is a national phase entry under 35 USC 371 of International Patent Application No. PCT/CN2022/089967 filed on Apr. 28, 2022, which is incorporated herein by reference in its entirety.

### TECHNICAL FIELD

The present disclosure relates to the field of display technologies, and in particular, to a display module and a display apparatus.

### BACKGROUND

Fingerprint identification technology refers to a technology that can obtain fingerprint information by sensing and analyzing signals of valleys and ridges of a fingerprint through a fingerprint identification module, which has many advantages such as high safety, easy and fast operation, and therefore widely used in electronic products. Fingerprint imaging may be realized through a variety of technologies such as optical imaging, capacitive imaging, ultrasonic imaging, in which the optical fingerprint identification technology has gradually become the mainstream of fingerprint identification technology due to its strong penetration ability, support for full-screen arrangement and simple product structure design, and therefore is widely used in the electronic products.

### SUMMARY

In an aspect, a display module is provided. The display module includes a display panel and a support layer.

The support layer is disposed on a non-display side of the display panel, and the support layer includes a support plate and a first support part connected with the support plate. The support plate is provided with a first hole, and the first support part is disposed in the first hole; and at least a portion of the first support part is light permeable. A side surface of the support plate proximate to the display panel is substantially flush with a side surface of the first support part proximate to the display panel; and a thickness of the support layer is in a range of approximately 10 μm to approximately 200 μm, inclusive.

In some embodiments, the entire first support part is made of a transparent material, and a side wall of the first support part in a thickness direction of the display panel is fixedly connected to a wall of the first hole.

In some embodiments, a material of the first support part includes flexible glass or polymethyl methacrylate; and/or a light transmittance of the first support part is greater than or equal to 90%; and/or an elastic modulus of the first support part is greater than or equal to 3 Gpa.

In some embodiments, the support layer further includes an adhesive part. The adhesive part is disposed between the first support part and the wall of the first hole, and the support plate and the first support part are connected by the adhesive part.

In some embodiments, a material of the adhesive part includes a light shielding material.

In some embodiments, a material of the adhesive part includes a single-component epoxy adhesive; and/or a viscosity of the adhesive part is in a range of 10000 cP to 20000 cP, inclusive; and/or a distance between the first support part and the wall of the first hole is in a range of 15 μm to 500 μm, inclusive.

In some embodiments, the first support part includes a plurality of support strips, and at least two of the plurality of support strips are connected to a wall of the first hole; and the plurality of support strips and the wall of the first hole define a plurality of second holes.

In some embodiments, the plurality of support strips and the wall of the first hole are connected to form a honeycomb structure or a grid structure.

In some embodiments, an orthographic projection of a second hole on the display panel is in a shape of a regular polygon, a circle or an ellipse.

In some embodiments, the display panel includes a plurality of sub-pixels, and orthographic projections of the plurality of support strips on the display panel are staggered with light emitting regions of the plurality of sub-pixels.

In some embodiments, a width of a support strip is less than or equal to a distance between light emitting regions of two adjacent sub-pixels; and/or an area of a second hole is greater than or equal to an area of a light emitting region of a sub-pixel.

In some embodiments, the display module further includes a buffer layer disposed on a side of the support layer proximate to the display panel, and the buffer layer includes a second support part that is light permeable.

In some embodiments, the entire buffer layer is made of a transparent material.

In some embodiments, a material of the buffer layer includes thermoplastic polyurethane elastomer rubber, and/or a light transmittance of the buffer layer is greater than or equal to 92%; and/or an elastic modulus of the buffer layer is in a range of 0.1 Gpa to 0.15 Gpa, inclusive.

In some embodiments, the buffer layer is provided with a third hole, and the second support part is disposed in the third hole.

In some embodiments, a material of the second support part includes polyethylene terephthalate; and/or a light transmittance of the second support part is greater than or equal to 90%; and/or an elastic modulus of the second support part is in a range of 0.5 Gpa to 1.5 Gpa, inclusive.

In some embodiments, the display module further includes an adhesive layer disposed on a side of the buffer layer proximate to the display panel, and the second support part is bonded to the adhesive layer.

In another aspect, a display apparatus is provided. The display apparatus includes the display module according to any of foregoing embodiments, and an optical device disposed on a non-display side of the display module.

In some embodiments, the display apparatus further includes a light shielding layer, disposed on a side, away from the display panel, of the support layer in the display module and covering the optical device.

In some embodiments, an orthographic projection of the first hole of the support plate of the support layer on the display panel is in a range of an orthographic projection of the light shielding layer on the display panel; or the orthographic projection of the first hole of the support plate of the support layer on the display panel is in the range of the orthographic projection of the light shielding layer on the display panel; and the first support part of the support layer includes a plurality of second holes, orthographic projections of the plurality of second holes on the display panel are in the range of the orthographic projection of the light shielding layer on the display panel.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person having ordinary skill in the art can obtain other drawings according to these accompanying drawings. In addition, the accompanying drawings to be described below may be regarded as schematic diagrams, and are not limitations on an actual size of a product, an actual process of a method and an actual timing of a signal involved in the embodiments of the present disclosure.

FIG. 1 is a top view of a display apparatus, in accordance with some embodiments;

FIG. 2 is a structural diagram of a display apparatus, in accordance with some embodiments;

FIG. 3 is a structural diagram of another display apparatus, in accordance with some embodiments;

FIG. 4 is a cross-section taken along the section line A-A′ in FIG. 1;

FIG. 5 is a cross-section taken along the section line B-B′ in FIG. 1;

FIG. 6 is another cross-section taken along the section line B-B′ in FIG. 1;

FIG. 7 is yet another cross-section taken along the section line B-B′ in FIG. 1;

FIG. 8 is a structural diagram of a support layer in FIG. 7;

FIG. 9 is yet another cross-section taken along the section line B-B′ in FIG. 1;

FIG. 10 is a structural diagram of a support layer in FIG. 9;

FIG. 11 is an enlarged view of the region C in FIG. 10;

FIG. 12A is yet another cross-section taken along the section line B-B′ in FIG. 1;

FIG. 12B is a diagram illustrating a stress simulation analysis of the display apparatus corresponding to FIG. 12A;

FIG. 13 is yet another cross-section taken along the section line B-B′ in FIG. 1;

FIG. 14 is yet another cross-section taken along the section line B-B′ in FIG. 1;

FIG. 15 is yet another cross-section taken along the section line B-B′ in FIG. 1;

FIG. 16 is yet another cross-section taken along the section line B-B′ in FIG. 1; and

FIG. 17 is yet another cross-section taken along the section line B-B′ in FIG. 1.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed in an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above term do not necessarily refer to the same embodiment(s) or example(s). In addition, specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of/the plurality of” means two or more unless otherwise specified.

In the description of some embodiments, the expressions “electrically connected” and “connected” and derivatives thereof may be used. For example, the term “electrically connected” may be used in the description of some embodiments to indicate that two or more components are in direct physical contact or electrical contact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

In the description of the present disclosure, it will be understood that, orientations or positional relationships indicated by the terms such as “center”, “longitudinal”, “transverse”, “length”, “width”, “vertical”, “horizontal”, “inner”, “outer” are based on orientations or positional relationships shown in the drawings, which is merely for convenience in description of the present disclosure and simplifying the description, but not to indicate or imply that the indicated apparatus or element must have a specific orientation, or be constructed and operated in a specific orientation.

It will be understood that, in a case where a layer or element is referred to be on another layer or substrate, it may be that the layer or element is directly on the another layer or substrate, or it may be that there is intermediate layer(s) between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in an apparatus, and are not intended to limit the scope of the exemplary embodiments.

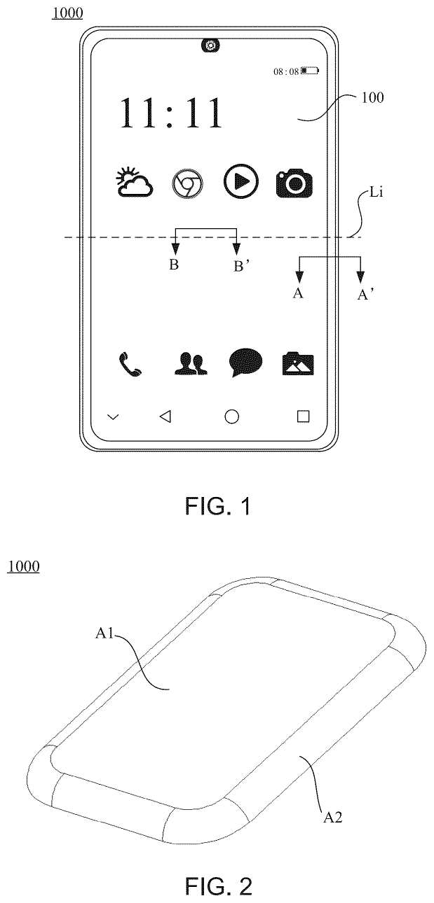

FIG. 1 is a top view of a display apparatus provided by some embodiments of the present disclosure. The display apparatus 1000 may be any device that can display images whether in motion (e.g., a video) or stationary (e.g., a still image), and regardless of text or image. More specifically, it is expected that the embodiments may be implemented in or associated with a plurality of electronic devices. The plurality of electronic devices may include (but is not limit to), for example, mobile telephones, wireless devices, personal data assistants (PAD), hand-held or portable computers, Global Position System (GPS) receivers/navigators, cameras, MPEG-4 Part 14 (MP4) video players, video cameras, game consoles, watches, clocks, calculators, television (TV) monitors, flat panel displays, computer monitors, vehicle-mounted displays (such as odometer displays, etc.), navigators, cockpit controllers and/or displays, displays with camera view (such as rear view camera displays in vehicles), electronic photos, electronic billboards or indicators, projectors, building structures, packagings and aesthetic structures (such as a display for an image of a piece of jewelry), etc. FIG. 1 illustrates the display apparatus 1000 being a mobile phone as an example.

The display apparatus 1000 may be one of a curved display apparatus, a foldable display apparatus, or a rollable display apparatus.

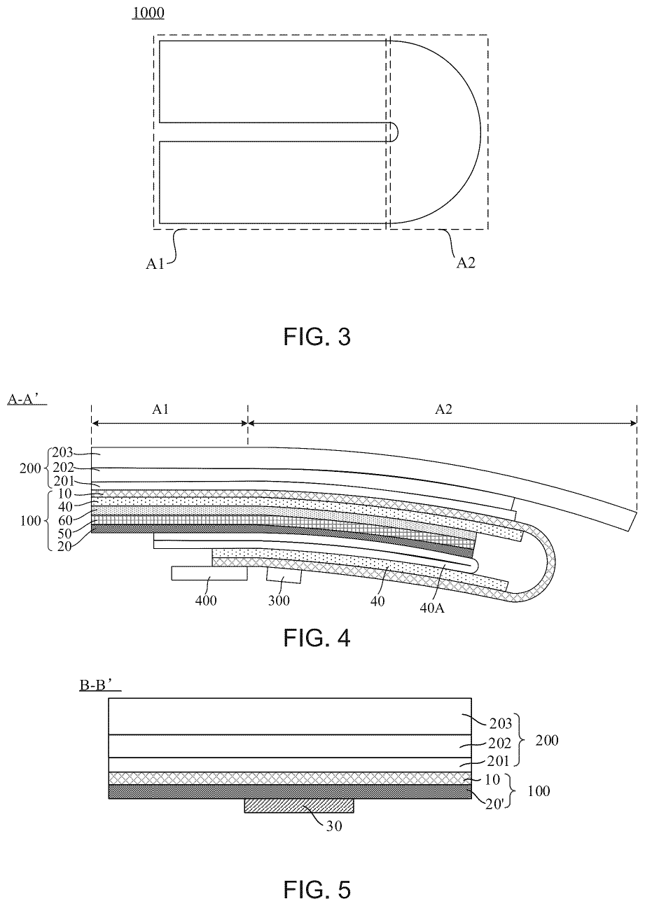

As shown in FIG. 2 and FIG. 3, the display apparatus 1000 includes a main display region A1 and a curved display region A2, where the curved display region A2 is a bent, rolled or folded portion of the display apparatus 1000.

For example, the display apparatus 1000 may be a display apparatus having a curved surface on at least one side. For example, the curved display region A2 may be located on any one or more of a left side, a right side, an upper side or a lower side of the main display region A1, which is not particularly limited herein.

For example, as shown in FIG. 2, the display apparatus 1000 may be a display apparatus having curved surfaces on all sides, and the curved display region A2 is disposed around the main display region A1.

Optionally, the display apparatus 1000 may be a foldable display apparatus. For example, as shown in FIG. 3, the curved display region A2 is located at one side of the main display region A1 after the display apparatus 1000 is folded along the axis Li in FIG. 1.

For example, an outline of the display apparatus 1000 is substantially rectangular. It will be noted that the term “substantially rectangular” means that the outline of the display apparatus 1000 is in a shape of a rectangle as a whole, but is not limited to a standard rectangle. That is, a range of the meaning of “rectangle” herein includes not only a substantial rectangle but also a shape similar to the rectangle in consideration of process conditions. For example, long and short sides of the rectangle are curved at each intersecting position (i.e., corners), i.e., the corners are smooth, so that the outline of the display apparatus 1000 is in a shape of a rounded rectangle in plan view.

As shown in FIG. 4, the display apparatus 1000 includes a display module 100 and an encapsulation assembly 200. The encapsulation assembly 200 is disposed on a side of the display module 100.

In some embodiments, the encapsulation assembly 200 includes a polarizer 201, an adhesive layer 202 and a cover plate 203.

The polarizer 201 is disposed on a display side of the display module 100 (i.e., a surface from which light is emitted to display an image), and corresponds to at least the main display region A1, which may reduce a light reflectivity of the display side of the display module 100, and improve a display contrast of the display apparatus 1000.

The cover plate 203 is disposed on a side of the polarizer 201 away from the display module 100, which is used to protect the display module 100.

The adhesive layer 202 is disposed between the polarizer 201 and the cover plate 203, which is used to bond the polarizer 201 to the cover plate 203.

In some embodiments, referring to FIG. 4, the display apparatus 1000 further includes a display driver chip 300 and a flexible circuit board 400.

The display driver chip 300 is disposed on a side of the display module 100 away from the encapsulation assembly 200, and is electrically connected to the display module 100: the flexible circuit board 400 is disposed on the side of the display module 100 away from the encapsulation assembly 200, and is electrically connected to the display module 100. The display driver chip 300 and the flexible circuit board 400 are used to provide the display module 100 with data signals required for displaying images.

Optionally, the display apparatus may further include a housing.

In some embodiments, as shown in FIG. 5, the display apparatus 1000 further includes an optical device 30 disposed on a non-display side (a side opposite to the display side) of the display module 100.

By providing the optical device 30 on the non-display side of the display module 100, the optical device 30 is avoided to occupy the display side of the display module 100, which achieves a maximum utilization of a display area of the display module 100, and is conducive to achieving a full-screen design of the display apparatus 1000.

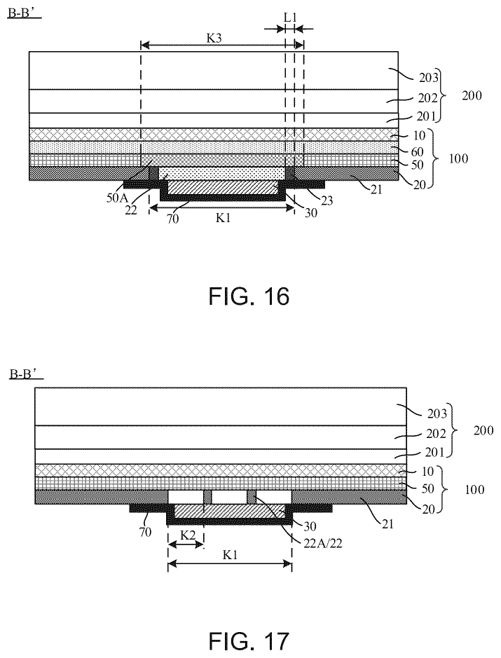

For example, the display apparatus 1000 furthers includes a light shielding layer covering the optical device 30 (referring to FIG. 16), so as to prevent ambient light from interfering with the optical device 30 and improve an operation efficacy of the optical device 30.

As shown in FIG. 5, the display module 100 includes a display panel 10 and a support layer 20′ disposed on a side of the display panel 10.

The support layer 20′ corresponds to the main display region A1 and the curved display region A2. That is, before the display panel 10 is bent to form a curved surface, an orthographic projection of the support layer 20′ on the display panel 10 is located in both the main display region A1 and the curved display region A2. The display panel 10, the adhesive layer 202 and the cover plate 203 are all flexible structures, and the support layer 20′ is configured to provide rigid support for the flexible structures, so as to avoid an undesirable deformation generated in the flexible structures, and ensure the display panel 10 to be able to have and maintain a certain shape. For example, the support layer 20′ may be made of a SUS304 steel sheet.

For example, the optical device 30 is an optical fingerprint identification device. The optical fingerprint identification device (optical device 30) is provided under the screen, i.e., disposed on the non-display side of the display panel 10. When fingerprint detection is performed, light emitted by the display panel 10 is irradiated onto a finger on the display side of the display panel 10, and the light is reflected to form return light carrying fingerprint information, and the return light passes through the display panel 10 and is irradiated onto the optical fingerprint identification device to perform the fingerprint identification detection.

The inventors of the present disclosure have found that, in a case where the display apparatus 1000 is a curved display apparatus, especially in a case where the display apparatus 1000 is a foldable display apparatus, the support layer 20′ needs to provide a certain supporting force, and thus the material thereof is a rigid material such as stainless steel, and the light transmittance is poor. In a case where the optical device 30 is disposed under the screen, the return light is difficult to penetrate through the support layer 20′, which results in that the optical device 30 is difficult to collect information of enough return light. As a result, the function of the optical device 30 is implemented with poor results, for example, the fingerprint identification device has low accuracy and speed of fingerprint identification.

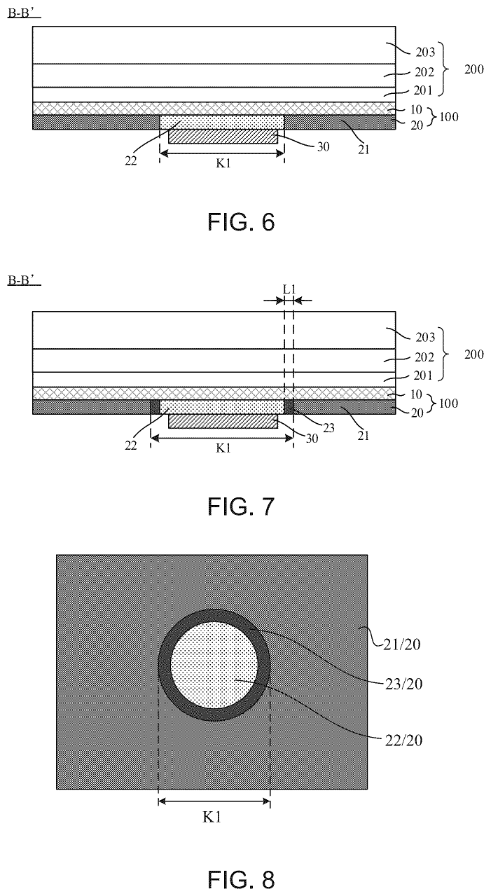

In order to solve the above problems, as shown in FIG. 6, embodiments of the present disclosure provide a display module 100, which includes a display panel 10 and a support layer 20.

The display panel 10 may be a liquid crystal display panel or a photoluminescent display panel. In a case where the display panel 10 is an electroluminescent display panel, the electroluminescent display panel may be an organic electroluminescent display panel (organic light emitting diode (OLED) display panel) or a quantum dot electroluminescent display panel (quantum dot light emitting diode (QLED) display panel). In a case where the display panel 10 is a photoluminescent display panel, the photoluminescent display panel may be a quantum dot photoluminescent display panel.

The display panel 10 has a display side and a non-display side, where the display side is a side of the display panel 10 on which images are displayed, and the non-display side is a side of the display panel 10 facing away from the display side.

As shown in FIG. 6, the support layer 20 is disposed on the non-display side of the display panel 10. The support layer 20 includes a support plate 21 and a first support part 22 connected with the support plate 21, the support plate 21 is provided with a first hole K1, and the first support part 22 is disposed in the first hole K1.

For example, the first hole K1 is in a shape of a circle, an ellipse or a polygon in top view.

As shown in FIG. 6, a side surface of the support plate 21 proximate to the display panel 10 is substantially flush with a side surface of the first support part 22 proximate to the display panel 10. That is, regions of a side surface of the support layer 20 proximate to the display panel 10 are substantially located on a same plane, so that the support layer 20 may provide uniform support for each region of the display panel 10, and the display panel 10 is prevented from being dented or protruded due to unevenness of the support layer 20. In this way, the yield of the display apparatus 1000 is prevented from being affected.

A thickness of the support layer 20 is in a range of approximately 10 μm to approximately 200 μm, inclusive, such as 10 μm, 18 μm, 30 μm, 40.5 μm, 60.78 μm, 80 μm, 92 μm, 100 μm, 135.5 μm, 178 μm or 200 μm.

By controlling the thickness of the support layer 20 to be in the range of approximately 10 μm to approximately 200 μm, inclusive, the support layer 20 may provide sufficient supporting force for the flexible structures in the display apparatus 1000, and moreover, the increase of the overall thickness of the display module 100 and even the display apparatus 1000 is avoided, which is beneficial to realizing the light and thin design of the display apparatus 1000.

For example, a material of the support plate 21 is a rigid material, for example, the material of the support plate 21 is stainless steel. In this case, the support plate 21 is configured to provide rigid support for the flexible structures in the display apparatus 1000, which ensures that the display apparatus 1000 can form and maintain a certain form.

The material of the support plate 21 is, for example, copper, silver, steel, aluminum, or an aluminum alloy, which has a strong heat dissipation capability. In this case, the support plate 21 is configured to dissipate heat of the display apparatus 1000 as a heat dissipation film layer.

At least a portion of the first support part 22 is light permeable. For example, the first support part 22 also has a certain supporting force.

For example, a light transmittance of the first support part 22 is greater than or equal to 65%. For example, the light transmittance of the first support part 22 is 65%, 70%, 72%, 80%, 90%, 93%, or the like.

By setting the light transmittance of the first support part 22 to be greater than or equal to 65%, the first support part 22 can provide a light transmission channel for the optical device 30 while satisfying the supporting force and avoiding the display panel 10 from sinking at the first hole K1.

As shown in FIG. 6, for example, the optical device 30 is disposed on a side of the first support part 22 away from the display panel 10. An orthographic projection of the optical device 30 on the display panel 10 is located in a range of an orthographic projection of the first support part 22 on the display panel 10. That is, the optical device 30 and the first support part 22 overlap each other in a thickness direction of the display panel 10.

For example, the orthographic projection of the optical device 30 on the display panel 10 is located in the range of the orthographic projection of the first support part 22 on the display panel 10.

It will be noted that the optical device 30 may be a device capable of realizing a specific function by means of an optical sensor therein, such as an under-screen camera, a fingerprint identification device, a 3D face identification device, an iris identification device, a proximity sensor, or the like.

In the display module 100 provided by the embodiments of the present disclosure, by providing the support layer 20 with the support plate 21 and the first support part 22 which can transmit light, the support layer 20 may satisfy the support effect on the flexible structures (e.g., the display panel 10, the adhesive layer 202, the cover plate 203, and the like) in the display apparatus 1000, and the light transmittance of the support layer 20 at a position corresponding to the optical device 30 may be increased, so that the return light can effectively reach the non-display side of the display panel 10, which ensures that the optical device 30 can effectively realize its specific function. In this way, the optical device 30, such as an optical fingerprint identification device, may be effectively applied to a flexible display apparatus, and in particularly may be applied to a foldable display apparatus with a large supporting requirement on the support layer 20, so that application scenarios of the optical device 30 are expanded.

In exemplary embodiments, as shown in FIG. 4, the display module 100 further includes a back film 40.

The back film 40 is disposed on a side of the display panel 10 away from the encapsulation assembly 200. The back film 40 is used for protecting the non-display side of the display panel 10, and moreover, the back film 40 provides a certain supporting force for the bending of the display panel 10, so that the cracking caused by uneven stress when the display panel 10 is bent is avoided.

For example, as shown in FIG. 4, the back film 40 may include two parts separated from each other, where a portion of the back film 40 can be bent with the display panel 10. In this case, there is no material of the back film 40 between the two parts separated from each other, so that a bent portion of the display panel 10 is exposed, and the bending resistance of the bent portion of the display panel 10 may be reduced.

For example, the back film 40 is made of a flexible material.

For example, the material of the back film 40 may be a poly-terephthalic plastic, such as polyethylene terephthalate (PET). The material of the back film 40 may also be polyimide (PI) or cyclic olefin polymer (COP).

In exemplary embodiments, as shown in FIG. 4, the display module 100 further includes a curved layer 40A.

The curved layer 40A is disposed on a side of the back film 40 away from the display panel 10. The curved layer 40A has a preset curvature, and serves as a reference for bending angles of other structure layers (the display panel 10 and the encapsulation assembly 200) of the display module 100.

In some embodiments, as shown in FIG. 6, the first support part 22 is disposed in the first hole K1, and the first support part 22 is made of a transparent material. A side wall of the first support part 22, in a direction perpendicular to the display panel 10, is fixedly connected to a wall of the first hole K1.

For example, as shown in FIG. 6, the first support part 22 fills the entire first hole K1.

For example, the first support part 22 has a certain support force.

For example, a side surface of the first support part 22 proximate to the display panel 10 is on a same plane as a side surface of the support plate 21 proximate to the display panel 10, and a side surface of the first support part 22 away from the display panel 10 is on another same plane as a side surface of the support plate 21 away from the display panel 10. It is possible to avoid a situation where the display side of the display panel 10 is convex or concave due to the first support part 22 being raised or depressed relative to the support plate 21.

For example, an orthographic projection of the optical device 30 on the display panel 10 is located in a range of an orthographic projection of the first hole K1 on the display panel 10. For example, the diameter of the first hole K1 is greater than the maximum dimension of the optical device 30 in a direction parallel to the display side of the display panel 10. For example, a difference between the diameter of the first hole K1 and a dimension of the optical device 30 in the direction parallel to the display side of the display panel 10 is greater than or equal to 0.2 mm.

For example, the orthographic projection of the optical device 30 on the display panel 10 is located in the range of the orthographic projection of the first hole K1 on the display panel 10. That is, the first support part 22 is opposite the optical device 30 in the thickness direction of the display panel 10, and the orthographic projection of the optical device 30 on the display panel 10 is in the range of the orthographic projection of the first support part 22 on the display panel 10. It is possible to ensure that the return light can penetrate the support layer 20 to the maximum extent, thereby improving the sensitivity and accuracy of the optical device 30.

By providing the first hole K1 at a position corresponding to the optical device 30 in the support plate 21 and providing the first support part 22 that is light permeable in the first hole K1, the return light can penetrate through the support layer 20, the effect of collecting the information by the optical device 30 is effectively improved, and the optical device 30 may be effectively applied to a flexible display apparatus, such as a foldable display apparatus, without affecting the function realization effect thereof. Moreover, the first support part 22 has a certain supporting force, so that it is avoided that the flexible structures (e.g., the display panel 10, the adhesive layer 202, the cover plate 203, and the like) of the flexible display apparatus are recessed toward the first hole K1 due to a local poor supporting performance of the support layer 20 caused by the setting of the first hole K1, so that a poor phenomenon such as a concave may be avoided to occur on the display side of the display panel 10.

For example, the first support part 22 has at least one of the following three features.

A first feature is that the material of the first support part 22 may include ultra-thin flexible glass (UTG for short) or polymethyl methacrylate (PMMA). The thickness of the ultra-thin flexible glass may be less than or equal to 50 μm, such as 10 μm, 30 μm, 35 μm, or 45.8 μm. UTG or PMMA as the first support part 22 may satisfy the requirements of both the support layer 20 for light transmittance and supporting force.

A second feature is that the light transmittance of the first support part 22 is greater than or equal to 90%. For example, the light transmittance of the first support part 22 is 90.1%, 92%, 92.55%, 95%, or 98%. Therefore, the requirement of the optical device 30 on the light transmittance of the support layer 20 can be met in a case where the optical device 30 is arranged under the screen, and the operation efficacy of the optical device 30 is improved.

A third feature is that an elastic modulus of the first support part 22 is greater than or equal to 3 Gpa. For example, the elastic modulus of the first support part 22 is 3.5 Gpa, 3.51 Gpa, 3.513 Gpa, 3.6 Gpa, 4 Gpa, or 5 Gpa. In this way, it provides a certain supporting force and avoids the problem of the display panel 10 sinking at the first hole K1 due to insufficient supporting force.

By making the first support part 22 have a certain light transmittance and satisfy a certain elastic modulus, the first support part 22 can provide a certain supporting force and also satisfy the light transmittance required by the optical device 30, so that the optical device 30, for example, an optical fingerprint identification device, may be effectively applied to a flexible display apparatus, thereby improving the situation that the optical device 30 cannot be applied to a foldable display apparatus or cannot be efficiently applied to the foldable display apparatus.

In exemplary embodiments, as shown in FIG. 7 and FIG. 8, the support layer 20 further includes an adhesive part 23.

The adhesive part 23 is disposed between the first support part 22 and the wall of the first hole K1, and the support plate 21 and the first support part 22 are connected by the adhesive part 23.

By providing the adhesive part 23 between the first support part 22 and the wall of the first hole K1, the first support part 22 is firmly fixed in the first hole K1, and the defect that the display side of the display panel 10 is convex or concave due to a situation that the first support part 22 is closer to or farther away from the display panel 10 relative to the support plate 21 under the action of an external force is avoided.

For example, a material of the adhesive part 23 includes alight shielding material. For example, the adhesive part 23 is made of a black non-light transmission material.

By providing the light shielding material as the adhesive part 23, interference of ambient light to the optical device 30 is reduced, and accuracy of information acquired by the optical device 30 is improved.

For example, an orthographic projection of the adhesive part 23 on the display panel 10 is non-overlapping with an orthographic projection of the optical device 30 on the display panel 10. That is, the adhesive part 23 and the optical device 30 are non-overlapping with each other in the thickness direction of the display panel 10, thereby preventing the adhesive part 23 from blocking light emission and collection of the optical device 30, and improving accuracy and speed of function realization of the optical device 30.

For example, the adhesive part 23 has at least one of the following two features.

A first feature is that the material of the adhesive part 23 includes a single-component epoxy adhesive.

A second feature is that a viscosity of the adhesive part 23 is in a range of 10000 cP to 20000 cP, inclusive. For example, the viscosity of the adhesive part 23 is 10000 cP, 12000 cP, 15300 cP, or 20000 cP.

By controlling the viscosity of the adhesive part 23 to be in the range of 10000 cP to 20000 cP, inclusive, it is possible to ensure the bonding strength of the adhesive part 23 while reducing the fluidity of the adhesive part 23, thereby avoiding overflow of the adhesive part 23 during the bonding process.

As shown in FIG. 7 and FIG. 8, a distance L1 between the first support part 22 and the wall of the first hole K1 is in a range of 15 μm to 500 μm, inclusive. That is, a thickness (dimension in a direction perpendicular to the inner wall of the first hole K1) of the adhesive part 23 is in the range of 15 μm to 500 μm, inclusive. For example, the thickness of the adhesive part 23 is 15 μm, 20 μm, 50 μm, 75 μm, 100 μm, 172.5 μm, 200 μm, 350 μm, or 500 μm.

By setting the material, viscosity, dimension and the like of the adhesive part 23, the first support part 22 is stably disposed in the first hole K1, so that the side surface of the first support part 22 proximate to the display panel 10 and the side surface of the support plate 21 proximate to the display panel 10 are on the same plane, and the side surface of the first support part 22 away from the display panel 10 and the side surface of the support plate 21 away from the display panel 10 are on the same plane. In this way, the situations of concavity or convexity and the like on the display side of the display panel 10 are avoided.

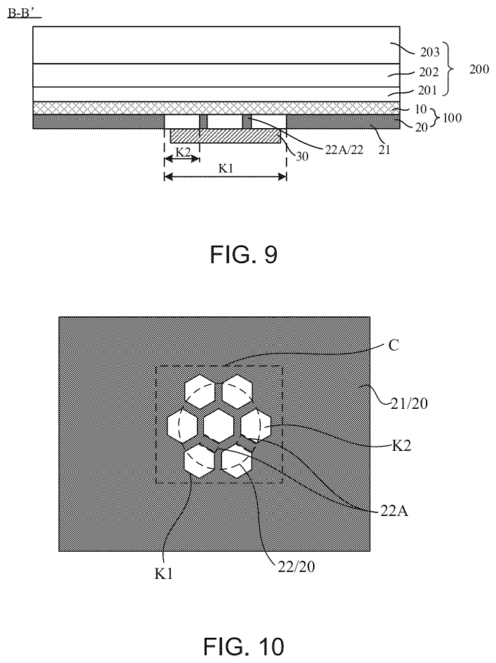

In some embodiments, as shown in FIG. 9, the first support part 22 includes a plurality of support strips 22A, at least two support strips 22A are connected to the wall of the first hole K1. The plurality of support strips 22A and the wall of the first hole K1 define a plurality of second holes K2. At least a portion of the wall of the first hole K1 serve as walls of the second holes K2.

For example, the plurality of support strips 22A are fixedly connected or integrally formed with the support plate 21.

For example, a thickness (dimension in the direction perpendicular to the display side of the display panel 10) of the support strip 22A is substantially equal to the thickness (dimension in the direction perpendicular to the display side of the display panel 10) of the support plate 21.

For example, a side surface of the support strip 22A proximate to the display panel 10 is on a same plane as the side surface of the support plate 21 proximate to the display panel 10, and a side surface of the support strip 22A away from the side surface of the display panel 10 is on another same plane as the side surface of the support plate 21 away from the display panel 10. It is possible to avoid a situation where the support strip 22A is raised or depressed with respect to the support plate 21, thereby avoiding a situation where the display-side surface of the display panel 10 is convex or concave.

For example, two adjacent second holes K2 are provided with one support strip 22A therebetween.

For example, an orthographic projection of the second hole K2 on the display panel 10 is in a shape of a regular polygon, a circle or an ellipse.

For example, an area of an orthographic projection of each second hole K2 on the display panel 10 is less than or equal to 0.2 times of the orthographic projection of the optical device 30 on the display panel 10. That is, the optical device 30 corresponds to the plurality of second holes K2 each having a size less than that of the optical device 30.

The plurality of second holes K2 with the small size may prevent the flexible structures of the display apparatus 1000 from being depressed, and moreover, the plurality of second holes K2 may ensure that the support layer 20 has a certain light transmittance, thereby improving the applicability of the optical device 30 in the flexible display apparatus.

The orthographic projection of the optical device 30 on the display panel 10 is located in a region where orthographic projections of the plurality of second holes K2 on the display panel 10 are located, so that the return light may penetrate the support layer 20 through the plurality of second holes K2 to the maximum extent, thereby improving the sensitivity and accuracy of the optical device 30.

For example, the light transmittance of the entire first support part 22 for providing the plurality of second holes K2 is substantially greater than or equal to 65%.

For example, as shown in FIG. 10, the plurality of support strips 22A and the wall of the first hole K1 are connected to form a honeycomb structure or a grid structure. The honeycomb structure or grid structure can hold up the flexible structures of the display apparatus 1000, so as to provide a certain supporting force for the flexible structures, and effectively avoid undesirable deformation generated in the flexible structures, for example, avoid the concave generated by the display side of the display panel 10 at the position corresponding to the optical device 30 due to the depression of the flexible structures.

By designing that the at least two of the plurality of support strips 22A of the first support part 22 are connected to the wall of the first hole K1, the plurality of support strips 22A and the wall of the first hole K1 can define the plurality of second holes K2. After the optical device 30 is provided, in a case where the orthographic projection of the optical device 30 on the display panel 10 is located in the region where the orthographic projection of the plurality of second holes K2 on the display panel 10 are located, the first support part 22 may be made grid-like. Openings in the grid-like first support part 22, i.e., the second holes K2, provide the optical device 30 with light transmission channels, thereby increasing the light transmission of the support layer 20 and enhancing the applicability of the optical device 30 in the flexible display apparatus. Moreover, ribs (i.e., the support strips 22A) in the grid-like first support part 22 may provide a certain supporting force to avoid deformation of the flexible structures in the display apparatus 1000 at the position corresponding to the optical device 30, such as sinking, resulting in undesirable phenomena such as the concave of the display side of the display panel 10.

Therefore, the display module 100 provided by embodiments of the present disclosure may both improve the applicability of the optical device 30 in a flexible display apparatus and ensure the original structural characteristics of the flexible display apparatus, thereby avoiding deformation of the flexible structures in the flexible display apparatus due to the setting of the optical device 30.

For example, the second hole K2 may be filled with UTG material or PMMA material, so that in a case where the light transmittance is satisfied, the supporting force of the first support part 22 may be further increased and the strength of the support layer 20 may be further increased.

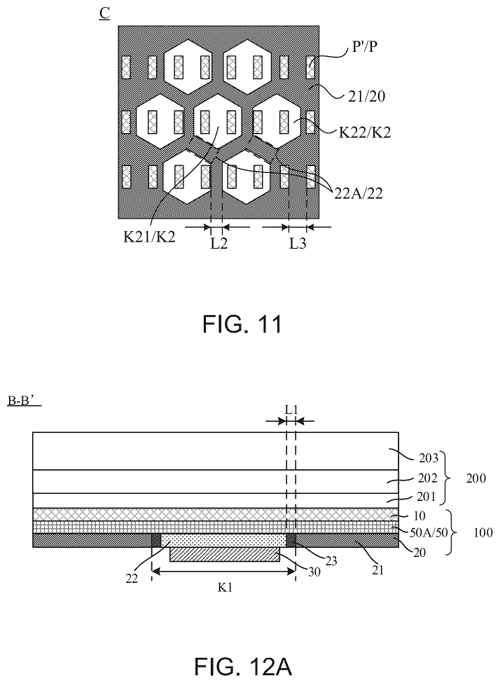

In exemplary embodiments, as shown in FIG. 11, the display panel 10 includes a plurality of sub-pixels P.

For example, the plurality of sub-pixels P are arranged in an array, and the sub-pixels P are capable of emitting color light, and each sub-pixel P has a respective light emitting region P from which the color light emitted by the sub-pixel P is emitted.

Orthographic projections of the support strips 22A on the display panel 10 are mutually staggered with the light emitting regions P′ of the sub-pixels P. For example, a support strip 22A is located between light emitting regions P′ of two adjacent sub-pixels P.

For example, a width L2 of the support strip 22A is less than or equal to a distance L3 between the light emitting regions P′ of the two adjacent sub-pixels P.

For example, if the distance L3 between the light emitting regions P′ of the two adjacent sub-pixels P is substantially 50 μm, the width L2 of the support strip 22A is substantially less than or equal to 50 μm.

For example, an area of a second hole K2 is greater than or equal to an area of a light emitting region P′ of a sub-pixel P.

For example, some light emitting regions P correspond to the second holes K2.

For example, the light emitting regions P′ of some sub-pixels P are in a range of orthographic projections of the second holes K2 on the display panel 10.

In exemplary embodiments, as shown in FIG. 11, the plurality of second holes K2 include a center hole K21 and multiple edge holes K22 uniformly arranged around the center hole K21.

For example, as shown in FIG. 11, the second hole K2 has a regular hexagon shape, and the plurality of second holes K2 include one center hole K21 and six edge holes K22 uniformly arranged around the center hole K21. Opposite edges of two adjacent second holes K2 are set parallel to each other so that the plurality of second holes K2 are evenly distributed, thereby facilitating a tendency that pressing force is evenly dispersed when the finger fingerprint test is performed.

The support layer 20 may be disposed in a foldable display apparatus, and a plurality of second holes K2 each in a regular hexagon shape are formed in the first support part 22. Through simulation tests, pressure is applied to region around the second holes K2 under the pressure condition of 600 g for 10 s, and the sagging amount is 0.2 mm, which may meet the requirement of the display apparatus 1000 on a fingerprint sensor.

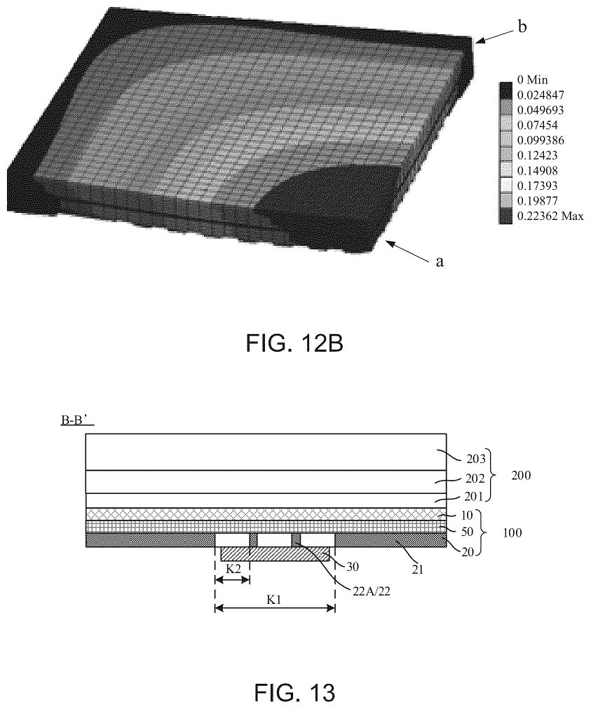

In some embodiments, as shown in FIG. 12A, the display module 100 further includes a buffer layer 50 disposed on a side of the support layer 20 proximate to the display panel 10.

For example, a material of the buffer layer 50 includes foam.

The buffer layer 50 is configured to absorb stress and external impact applied to the display panel 10 during the assembling process and the subsequent use process, so as to effectively protect the display panel 10 and other components.

The buffer layer 50 includes a second support part 50A. The second support part 50A is light permeable.

For example, an orthographic projection of the optical device 30 on the display panel 10 is located in a range of an orthographic projection of the second support part 50A on the display panel 10. That is, a portion (i.e., the second support part 50A) of the buffer layer 50 corresponding to the optical device 30 is made of a transparent material, so that the buffer layer 50 is prevented from shielding the return light, the optical device 30 may effectively realize its specific function, and the applicability of the optical device 30 in the flexible display apparatus is further improved. In addition, the arrangement of a position where the optical device 30 is disposed is expanded, for example, the optical device 30 may be disposed even in a region where the buffer layer 50 is disposed in the display apparatus 1000, so that the optical device 30 may be disposed at an arbitrary position on the full screen of the display apparatus 1000.

An orthographic projection of the second support part 50A on the display panel 10 at least partially overlaps with an orthographic projection of the first support part 22 on the display panel 10. Moreover, the orthographic projection of the optical device 30 on the display panel 10 is located in a range of a portion where the orthographic projection of the second support part 50A on the display panel 10 and the orthographic projection of the first support part 22 on the display panel 10 overlap with each other, so that the support layer 20 and the buffer layer 50 are prevented from shielding the return light, and the effectiveness of the optical device 30 is improved.

In exemplary embodiments, as shown in FIG. 12A and FIG. 13, the entire buffer layer 50 is made of a transparent material. That is, the buffer layer 50 serves as the second support part 50A as a whole.

For example, the buffer layer 50 is provided thereon with an adhesive layer on both sides proximate to and away from the display panel 10.

For example, the buffer layer 50 has at least one of the following four features.

A first feature is that a material of buffer layer 50 includes thermoplastic polyurethane elastomer rubber (TPU), which may satisfy both a certain light transmittance and supporting force.

A second feature is that the light transmittance of the buffer layer 50 is greater than or equal to 92%. For example, the light transmittance of the buffer layer 50 is 92%, 93%, 93.5%, 94%, or 98%. By setting the light transmittance of the buffer layer 50 to be greater than or equal to 92%, the buffer layer 50 can provide a light transmission channel for the optical device 30, and the problem that the efficacy of the optical device 30 is reduced because the buffer layer 50 shields the optical device 30 is avoided.

A third feature is that an elastic modulus of the buffer layer 50 is in a range of 0.1 Gpa to 0.15 Gpa, inclusive. For example, the elastic modulus of the buffer layer 50 is 0.1 Gpa, 0.101 Gpa, 0.12 Gpa, 0.125 Gpa, 0.14 Gpa, or 0.15 Gpa. The elastic modulus of the buffer layer 50 is controlled to be in the range of 0.1 Gpa to 0.15 Gpa, inclusive, so that the buffer effect of the buffer layer 50 is realized, the buffer layer 50 can absorb stress and external force impact on the display panel 10 in the assembling process and the subsequent using process, and the display panel 10 and other components are effectively protected. In addition, the buffer layer 50 may have a certain supporting force, which is beneficial to implementing the folding design of the display apparatus 1000.

A fourth feature is that a thickness of the buffer layer 50 (a dimension thereof in a direction perpendicular to the display side of the display panel 10) is in a range of 0.1 mm to 0.12 mm, inclusive. For example, the thickness of the buffer layer 50 is 0.1 mm, 0.102 mm, 0.11 mm, or 0.12 mm, thereby ensuring the buffer effect of the buffer layer 50.

By setting the entire buffer layer 50 made of transparent material, it may meet the requirements of the optical device 30 on the light transmission of the buffer layer 50; and by setting the buffer layer 50 to have a certain elasticity, such as an elastic modulus of 0.15 Gpa, it may retain the role of the buffer layer 50 in absorbing stress and ensure the protective effect of the buffer layer 50 on the display panel 10 and other structures.

Referring to the stress simulation analysis diagram shown in FIG. 12B, taking the optical device 30 as an optical fingerprint identification device as an example, a stress analysis is performed on a position corresponding to the optical device 30 in the display apparatus 1000 in FIG. 12A, as shown in FIG. 12B, a stress applied to the display apparatus 1000 is uniformly diffused from a force application center a of a finger (i.e., a center where the optical device 30 is located) to an edge b of the display apparatus 1000, and a supporting effect is good.

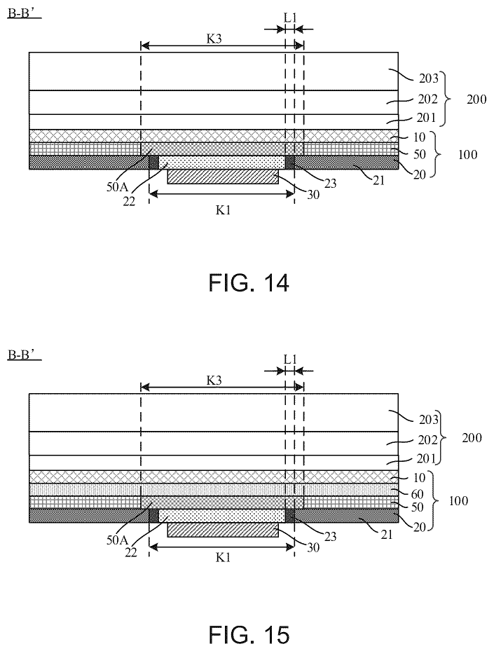

In exemplary embodiments, as shown in FIG. 14, the buffer layer 50 is provided with a third hole K3. The second support part 50A is disposed in the third hole K3.

For example, a material of a portion, except for the second support part 50A, of the buffer layer 50 includes foam.

A light transmitting part (i.e., the second support part 50A) with a supporting force is disposed in the third hole K3, so as to provide a certain supporting force for the flexible device of the display apparatus 1000 while ensuring the light transmittance requirement of the optical device 30 for the buffer layer 50, and also provide a certain buffering capacity at the position of the third hole K3, thereby avoiding the damage to the display panel 10, the optical device 30, or other structures at the position of the third hole K3 due to the fact that the third hole K3 is opened and the position of the third hole K3 cannot absorb the external impact force.

An orthographic projection of the optical device 30 on the display panel 10 is located in a range of an orthographic projection of the second support part 50A on the display panel 10, thereby ensuring that the return light smoothly penetrates the buffer layer 50 and avoiding the problem of the buffer layer 50 blocking the light of the optical device 30 and thereby reducing the efficacy of the optical device 30.

For example, the second support part 50A has at least one of the following three features.

A first feature is that a material of the second support part 50A includes polyethylene terephthalate (PET). The second support part 50A made of the PET material may satisfy the requirements of the buffer layer 50 for light transmittance, supporting force and buffering effect.

A second feature is that a light transmittance of the second support part 50A is greater than or equal to 90%. For example, the light transmittance of the second support part 50A is 90%, 91%, 92.5%, 95%, or 98%. Therefore, the requirement of the optical device 30 on the light transmittance of the buffer layer 50 in a case where the optical device is arranged under the screen may be met, and the effect of the optical device 30 is improved.

A third feature is that an elastic modulus of the second support part 50A is in a range of 0.5 Gpa to 1.5 Gpa, inclusive. For example, the elastic modulus of the second support part 50A is 0.5 Gpa, 0.65 Gpa, 1 Gpa, or 1.5 Gpa, so as to provide a certain supporting force, and avoid the problem that the display panel 10 sinks at the third hole K3 due to insufficient supporting force; moreover, the buffer capacity of the second support part 50A is maintained, and the impact resistance of the buffer layer 50 is ensured.

For example, the elastic modulus of the second support part 50A is substantially equal to the elastic modulus of the buffer layer 50, thereby ensuring that a film layer in which the buffer layer 50 is located has uniform impact resistance.

For example, as shown in FIG. 14, in a case where the support layer 20 includes the support plate 21 and the first support part 22, the support plate 21 is provided with the first hole K1, and the first support part 22 is provided in the first hole K1, an orthographic projection of the first hole K1 on the display panel 10 is in a range of an orthographic projection of the third hole K3 on the display panel 10. For example, a radius of the third hole K3 is greater than a radius of the first hole K1. For example, a difference between the radius of the third hole K3 and the radius of the first hole K1 is greater than or equal to 0.2 mm. Therefore, the return light may be ensured to effectively penetrate the buffer layer 50 to the maximum extent after penetrating the support layer 20, and the efficacy of the optical device 30 may be improved.

In some embodiments, as shown in FIG. 15, the display module 100 further includes an adhesive layer 60 disposed on a side of the buffer layer 50 proximate to the display panel 10.

The adhesive layer 60 is configured to attach the buffer layer 50 to a side of the display panel 10, and prevent the buffer layer 520 from falling off, thereby enhancing the impact resistance of the buffer layer 50.

For example, the second support part 50A is adhered with the adhesive layer 60. Therefore, the second support part 50A is securely filled in the third hole K3, and the second support part 50A is prevented from protruding or sinking relative to the buffer layer 50, so as to prevent the display side of the display panel 10 from generating unevenness such as bulge or mark.

In some embodiments, as shown in FIG. 16 and FIG. 17, a light shielding layer 70 is disposed on a side of the support layer 20 in the display module 100 away from the display panel 10 and covers the optical device 30. The light shielding layer 60 covers the optical device 30, so as to prevent ambient light from interfering with the optical device 30, thereby improving the efficacy of the optical device 30.

In exemplary embodiments, as shown in FIG. 16, an orthographic projection of the first hole K1 in the support plate 21 of the support layer 20 on the display panel 10 is located in a range of an orthographic projection of the light shielding layer 30 on the display panel 10. The light shielding layer 60 covers the optical device 30 and also covers the first hole K1 in the support layer 20, so that it is ensured that all light passing through the first hole K1 comes from the optical device 30, interference of ambient light on the optical device 30 is avoided, and the efficacy of the optical device 30 is improved.

In exemplary embodiments, as shown in FIG. 17, in a case where the first support part 22 of the support layer 20 includes the plurality of second holes K2, orthographic projections of the plurality of second holes K2 on the display panel 10 are located in the range of the orthographic projection of the light shielding layer 30 on the display panel 10. The light shielding layer 60 covers the optical device 30 and also covers the second holes K2 in the support layer 20, so that it is ensured that all light passing through the second holes K2 comes from the optical device 30, interference of ambient light on the optical device 30 is avoided, and the efficacy of the optical device 30 is improved.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel; and
a support layer disposed on a non-display side of the display panel, the support layer including a support plate and a first support part connected with the support plate;
wherein the support plate is provided with a first hole, and the first support part is disposed in the first hole; and at least a portion of the first support part is light permeable;
a side surface of the support plate proximate to the display panel is substantially flush with a side surface of the first support part proximate to the display panel; and
a thickness of the support layer is in a range of approximately 10 μm to approximately 200 μm, inclusive.

2. The display module according to claim 1, wherein the entire first support part is made of a transparent material, and a side wall of the first support part in a thickness direction of the display panel is fixedly connected to a wall of the first hole.

3. The display module according to claim 1, wherein a material of the first support part includes flexible glass or polymethyl methacrylate; and/or
a light transmittance of the first support part is greater than or equal to 90%; and/or
an elastic modulus of the first support part is greater than or equal to 3 Gpa.

4. The display module according to claim 2, wherein the support layer further includes an adhesive part, wherein
the adhesive part is disposed between the first support part and the wall of the first hole, and the support plate and the first support part are connected by the adhesive part.

5. The display module according to claim 4, wherein a material of the adhesive part includes a light shielding material.

6. The display module according to claim 4, wherein a material of the adhesive part includes a single-component epoxy adhesive; and/or
a viscosity of the adhesive part is in a range of 10000 cP to 20000 cP, inclusive; and/or
a distance between the first support part and the wall of the first hole is in a range of 15 μm to 500 μm, inclusive.

7. The display module according to claim 1, wherein the first support part includes a plurality of support strips, and at least two of the plurality of support strips are connected to a wall of the first hole; and the plurality of support strips and the wall of the first hole define a plurality of second holes.

8. The display module according to claim 7, wherein the plurality of support strips and the wall of the first hole are connected to form a honeycomb structure or a grid structure.

9. The display module according to claim 7, wherein an orthographic projection of a second hole on the display panel is in a shape of a regular polygon, a circle or an ellipse.

10. The display module according to claim 7, wherein the display panel includes a plurality of sub-pixels, and orthographic projections of the plurality of support strips on the display panel are staggered with light emitting regions of the plurality of sub-pixels.

11. The display module according to claim 10, wherein a width of a support strip is less than or equal to a distance between light emitting regions of two adjacent sub-pixels; and/or
an area of a second hole is greater than or equal to an area of a light emitting region of a sub-pixel.

12. The display module according to claim 1, further comprising:
a buffer layer disposed on a side of the support layer proximate to the display panel, the buffer layer including a second support part that is light permeable.

13. The display module according to claim 12, wherein the entire buffer layer is made of a transparent material.

14. The display module according to claim 12, wherein a material of the buffer layer includes thermoplastic polyurethane elastomer rubber; and/or
a light transmittance of the buffer layer is greater than or equal to 92%; and/or
an elastic modulus of the buffer layer is in a range of 0.1 Gpa to 0.15 Gpa, inclusive.

15. The display module according to claim 12, wherein the buffer layer is provided with a third hole, and the second support part is disposed in the third hole.

16. The display module according to claim 12, wherein a material of the second support part includes polyethylene terephthalate; and/or
a light transmittance of the second support part is greater than or equal to 90%; and/or
an elastic modulus of the second support part is in a range of 0.5 Gpa to 1.5 Gpa, inclusive.

17. The display module according to claim 12, further comprising:
an adhesive layer disposed on a side of the buffer layer proximate to the display panel, the second support part being bonded to the adhesive layer.

18. A display apparatus, comprising:
the display module according to claim 1; and
an optical device disposed on a non-display side of the display module.

19. The display apparatus according to claim 18, further comprising:
a light shielding layer, disposed on a side, away from the display panel, of the support layer in the display module and covering the optical device.

20. The display apparatus according to claim 19, wherein an orthographic projection of the first hole of the support plate of the support layer on the display panel is in a range of an orthographic projection of the light shielding layer on the display panel; or
the orthographic projection of the first hole of the support olate of the support laver on the display panel is in the range of the orthographic projection of the light shielding laver on the display panel; and the first support part of the support layer includes a plurality of second holes, orthographic projections of the plurality of second holes on the display panel are in the range of the orthographic projection of the light shielding layer on the display panel.
